(19) United States
(12) Patent Application Publication
(10) Pub. No.: US 2009/0014049 A1
(43) Pub. Date: Jan. 15, 2009

(54) PHOTOVOLTAIC MODULE WITH INTEGRATED ENERGY STORAGE

(75) Inventors: Ilan GUR, San Francisco, CA (US); David Harris, Carpinteria, CA (US); Shefali Jaiswal, Dublin, CA (US); Puthur Paulson, Cupertino, CA (US); William Sanders, Mountain View, CA (US); Ben Tarbell, Palo Alto, CA (US)

Correspondence Address: FOLEY AND LARDNER LLP;SUITE 500, 3000 K STREET NW, WASHINGTON, DC, 20007, US

(73) Assignee: Miasole

(21) Appl. No.: 11/777,393

(22) Filed: Jul. 13, 2007

(51) Int. Cl. H01L 31/042

(52) U.S. Cl. 136/244

(57) ABSTRACT

A photovoltaic module includes a first photovoltaic cell, a second photovoltaic cell and an energy storage device, such as a battery or capacitor, integrated into the module.

### BACKGROUND

The present invention relates generally to a photovoltaic device and more particularly to photovoltaic modules having an integrated energy storage device.

### BACKGROUND

Many current collection methods in photovoltaic (“PV”) devices (which are also known as solar cell devices) use conductive inks that are screen printed on the surface of the PV cell. Alternative current collection methods involve conductive wires that are placed in contact with the cell.

A large portion of prior art PV cells are interconnected by using the so-called “tab and string” technique of soldering two or three conductive ribbons between the front and back surfaces of adjacent cells. Alternative interconnect configurations include shingled interconnects with conductive adhesives. Some prior art PV devices also include embossing of an adhesive backed metal foil to enhance conductivity of the substrate of the device.

However, the “tab and string” interconnection configuration suffers from poor yield and reliability due to solder joints that fail from thermal coefficient of expansion mismatches and defects, requires significant labor or capital equipment to assemble, and does not pack the cells in a PV module very closely. In addition, previous attempts at shingled interconnects have been plagued by reliability problems from degradation of the conductive adhesives used.

Most of the module products in the PV industry are solely passive devices that are configured with a fixed arrangement of cells, interconnections and output characteristics. In the vast majority of these module products, the cell to cell interconnections are made using a tab and string method by soldering copper strips between adjacent cells. Energy demands do not always synchronize with energy as it is generated by a PV array resulting in wasted energy or insufficient supply when there is demand. Batteries are commonly used in PV applications as separate ancillary devices, but not as an integrated component of the module.

### SUMMARY OF THE INVENTION

One embodiment of the invention includes a photovoltaic module comprising a first photovoltaic cell, a second photovoltaic cell, and an energy storage device integrated into the module.

### BRIEF DESCRIPTION OF THE DRAWINGS

FIGS. 1-5B are schematic illustrations of the components of photovoltaic modules of the embodiments of the invention. FIGS. 1, 2A, 2B, 3 and 4 are side cross sectional views. FIGS. 5A and 5B are three dimensional views.

FIGS. 5C, 6A and 6B are circuit schematics of modules of the embodiments of the invention.

FIG. 7 is a three dimensional view of an array of modules of an embodiment of the invention.

The dimensions of the components in the Figures are not necessarily to scale.

### DETAILED DESCRIPTION OF THE PREFERRED EMBODIMENTS

An embodiment of the invention includes a photovoltaic module which includes a plurality of PV cells and an energy storage device integrated into the module. The integrated energy storage device stores electrical energy generated by the PV cells and delivers the stored energy to the energy consumer on demand.

Preferably, the energy storage device is physically integrated into the module by being located between the encapsulating layers which encapsulate the PV cells, such as between the front and the back encapsulating layers. The front encapsulating layer may be an optically transparent polymer or glass layer which allows the sunlight to be transmitted to the PV cells. The back encapsulating layer may be a polymer or metal layer which is located below the PV cells. For PV cells manufactured on a flexible metal substrate, the metal substrate may be used as the back encapsulating layer.

For example, the energy storage device may comprise a thin film device which is electrically connected to one or more PV cells and is located together with the PV cells between the insulating encapsulating layers (which are also known as laminating layers) of the module. Thus, one or more energy storage devices are encapsulated together with the PV cells into the module.

The energy storage device may comprise a rechargeable, solid state, thin film battery such as a lithium battery, or a thin film capacitor, such as a supercapacitor or other type of capacitor, or any other energy storage device that can be laminated into the module stack. For example, flexible, thin film batteries, such as Flexion brand lithium polymer batteries, are available from Solicore of Lakeland, Fla.

Preferably but not necessarily, the energy storage device is integrated into a flexible PV module described in U.S. patent application Ser. No. 11/451,616, filed on Jun. 13, 2006, which is incorporated herein by reference in its entirety. This photovoltaic module includes at least two photovoltaic cells and a collector-connector. As used herein, the term “module” includes an assembly of at least two, and preferably three or more electrically interconnected photovoltaic cells, which may also be referred to as “solar cells”. The “collector-connector” is a device that acts as both a current collector to collect current from at least one photovoltaic cell of the module, and as an interconnect which electrically interconnects the at least one photovoltaic cell with at least one other photovoltaic cell of the module. In general, the collector-connector takes the current collected from each cell of the module and combines it to provide a useful current and voltage at the output connectors of the module.

This collector-connector (which can also be referred to as a flexible circuit or “decal”) preferably comprises an electrically insulating carrier and at least one electrical conductor which electrically connects one photovoltaic cell to at least one other photovoltaic cell of the module.

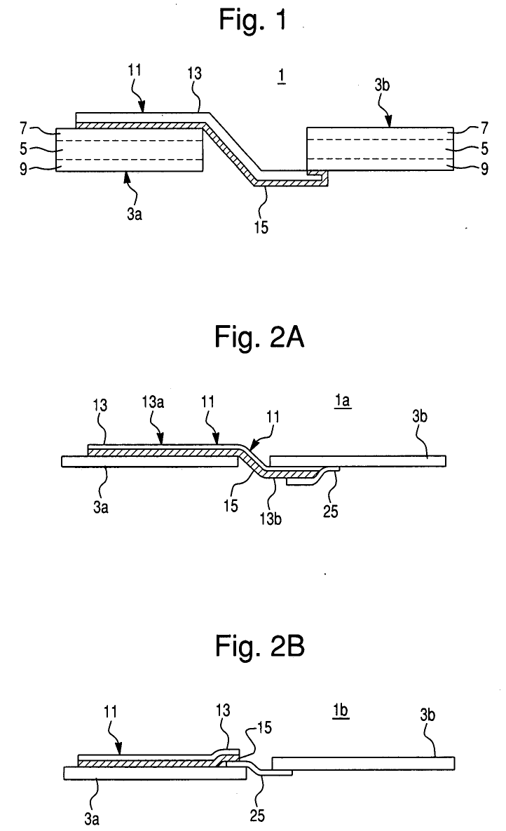

FIG. 1 schematically illustrates this module. The module 1 includes first and second photovoltaic cells 3a and 3b. It should be understood that the module 1 may contain three or more cells, such as 3-10,000 cells for example. Preferably, the first 3a and the second 3b photovoltaic cells are plate shaped cells which are located adjacent to each other, as shown schematically in FIG. 1. The cells may have a square, rectangular (including ribbon shape), hexagonal or other polygonal, circular, oval or irregular shape when viewed from the top.

Each cell 3a, 3b includes a photovoltaic material 5, such as a semiconductor material. For example, the photovoltaic semiconductor material may comprise a p-i-n or p-i-n junction in a Group IV semiconductor material, such as amorphous or crystalline silicon, a Group II-VI semiconductor material, such as CdTe or CdS, a Group I-III-VI semiconductor material, such as CuInSe₂ (CIS) or Cu(In,Ga)Se₂ (CIGS), and/or a Group III-V semiconductor material, such as GaAs or InGaP. The p-n junctions may comprise heterojunctions of different materials, such as CIGS/CdS heterojunction, for example. Each cell 3a, 3b also contains front and back side electrodes 7, 9. These electrodes 7, 9 can be designated as first and second polarity electrodes since electrodes have an opposite polarity. For example, the front side electrode 7 may be electrically connected to an n-side of a p-n junction and the back side electrode may be electrically connected to a p-side of a p-n junction. The electrode 7 on the front surface of the cells may be an optically transparent front side electrode which is adapted to face the Sun, and may comprise a transparent conductive material such as indium tin oxide or aluminum doped zinc oxide. The electrode 9 on the back surface of the cells may be a back side electrode which is adapted to face away from the Sun, and may comprise one or more conductive materials such as copper, molybdenum, aluminum, stainless steel and/or alloys thereof. This electrode 9 may also comprise the substrate upon which the photovoltaic material 5 and the front electrode 7 are deposited during fabrication of the cells.

The module 1 also contains the collector-connector 11, which comprises an electrically insulating carrier 13 and at least one electrical conductor 15. The collector-connector 11 electrically contacts the first polarity electrode 7 of the first photovoltaic cell 3a in such a way as to collect current from the first photovoltaic cell. For example, the electrical conductor 15 electrically contacts a major portion of a surface of the first polarity electrode 7 of the first photovoltaic cell 3a to collect current from cell 3a. The conductor 15 portion of the collector-connector 11 also directly or indirectly electrically contacts the second polarity electrode 9 of the second photovoltaic cell 3b to electrically connect the first polarity electrode 7 of the first photovoltaic cell 3a to the second polarity electrode 9 of the second photovoltaic cell 3b.

Preferably, the carrier 13 comprises a flexible, electrically insulating polymer film having a sheet or ribbon shape, supporting at least one electrical conductor 15. Examples of suitable polymer materials include thermal polymer olefin (TPO). TPO includes any olefins which have thermoplastic properties, such as polyethylene, polypropylene, polybutylene, etc. Other polymer materials which are not significantly degraded by sunlight, such as EVA, other non-olefin thermoplastic polymers, such as fluoropolymers, acrylics or silicones, as well as multilayer laminates and co-extrusions, such as PET/EVA laminates or co-extrusions, may also be used. The insulating carrier 13 may also comprise any other electrically insulating material, such as glass or ceramic materials. The carrier 13 may be a sheet or ribbon which is unrolled from a roll or spool and which is used to support conductor(s) 15 which interconnect three or more cells 3 in a module 1. The carrier 13 may also have other suitable shapes besides sheet or ribbon shape.

The conductor 15 may comprise any electrically conductive trace or wire. Preferably, the conductor 15 is applied to an insulating carrier 13 which acts as a substrate during deposition of the conductor. The collector-connector 11 is then applied in contact with the cells 3 such that the conductor 15 contacts one or more electrodes 7, 9 of the cells 3. For example, the conductor 15 may comprise a trace, such as silver paste, for example a polymer-silver powder mixture paste, which is spread, such as screen printed, onto the carrier 13 to form a plurality of conductive traces on the carrier 13. The conductor 15 may also comprise a multilayer trace. For example, the multilayer trace may comprise a seed layer and a plated layer. The seed layer may comprise any conductive material, such as a silver filled ink or a carbon filled ink which is printed on the carrier 13 in a desired pattern. The seed layer may be formed by high speed printing, such as rotary screen printing, flat bed printing, rotary gravure printing, etc. The plated layer may comprise any conductive material which can by formed by plating, such as copper, nickel, cobalt or their alloys. The plated layer may be formed by electroplating by selectively forming the plated layer on the seed layer which is used as one of the electrodes in a plating bath. Alternatively, the plated layer may be formed by electroless plating. Alternatively, the conductor 15 may comprise a plurality of metal wires, such as copper, aluminum, and/or their alloy wires, which are supported by or attached to the carrier 13. The wires or the traces 15 electrically contact a major portion of a surface of the first polarity electrode 7 of the first photovoltaic cell 3a to collect current from this cell 3a. The wires or the traces 15 also directly or indirectly electrically contact at least a portion of the second polarity electrode 9 of the second photovoltaic cell 3b to electrically connect this electrode 9 of cell 3b to the first polarity electrode 7 of the first photovoltaic cell 3a. The wires or traces 15 may form a grid-like contact to the electrode 7. The wires or traces 15 may include thin gridlines as well as optional thick busbars or buslines. If busbars or buslines are present, then the gridlines may be arranged as thin “fingers” which extend from the busbars or buslines.

FIGS. 2A and 2B illustrate modules 1a and 1b, respectively, in which the carrier film 13 contains conductive traces 15 printed on one side. The traces 15 electrically contact the active surface of cell 3a (i.e., the front electrode 7 of cell 3a) collecting current generated on that cell 3a. A conductive interstitial material may be added between the conductive trace 15 and the cell 3a to improve the conduction and/or to stabilize the interface to environmental or thermal stresses. The interconnection to the second cell 3b is completed by a conductive tab 25 which contacts both the conductive trace 15 and the back side of cell 3b (i.e., the back side electrode 9 of cell 3b). The tab 25 may be continuous across the width of the cells or may comprise intermittent tabs connected to matching conductors on the cells. The electrical connection can be made with conductive interstitial material, conductive adhesive, solder, or by forcing the tab material 25 into direct intimate contact with the cell or conductive trace. Embossing the tab material 25 may improve the connection at this interface. In the configuration shown in FIG. 2A, the collector-connector 11 extends over the back side of the cell 3b and the tab 25 is located over the back side of cell 3b to make an electrical contact between the trace 15 and the back side electrode of cell 3b. In the configuration of FIG. 2B, the collector-connector 11 is located over the front side of the cell 3a and the tab 25 extends from the front side of cell 3a to the back side of cell 3b to electrically connect the trace 15 to the back side electrode of cell 3b.

In summary, in the module configuration of FIGS. 2A and 2B, the conductor 15 is located on one side of the carrier film 13. At least a first part 13a of carrier 13 is located over a front surface of the first photovoltaic cell 3a such that the conductor 15 electrically contacts the first polarity electrode 7 on the front side of the first photovoltaic cell 3a to collect current from cell 3a. An electrically conductive tab 25 electrically connects the conductor 15 to the second polarity electrode 9 of the second photovoltaic cell 3b. Furthermore, in the module 1a of FIG. 2A, a second part 13b of carrier 13 extends between the first photovoltaic cell 3a and the second photovoltaic cell 3b, such that an opposite side of the carrier 13 from the side containing the conductor 15 contacts a back side of the second photovoltaic cell 3b. Other interconnect 11 configurations described in the above mentioned U.S. patent application Ser. No. 11/451,616 may also be used.

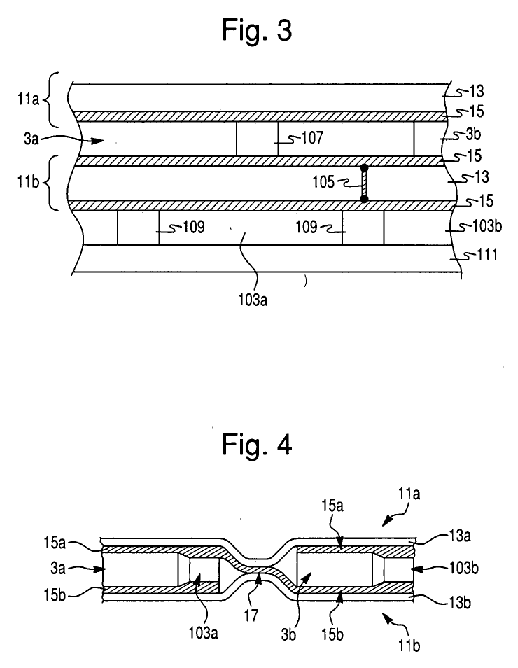

FIG. 3 schematically illustrates one embodiment of a multilevel module with integrated energy storage devices 103a, 103b which are located below the PV cells 3. In this embodiment, the laminated module 101 stack consist of multiple levels of the collector-connectors 11a, 11b in which the conductors 15 in each level are separated and isolated from each other by the respective insulating carriers 13 and/or other insulating encapsulant or laminate material. The collector-connectors 11 serve as the means of collecting current and interconnecting the PV cells 3a, 3b as well as interconnecting the energy storage device cells 103a, 103b. For example, collector-connector 11a interconnects the PV cells, while the collector-connector 11b interconnects the energy storage device cells 103a, 103b. Collector-connector 11b may have conductors 15 on both sides of the insulating carrier 13 to interconnect both the PV cells and energy storage device cells. Alternatively, two separate collector-connectors may be used instead of a single collector-connector containing conductors on both sides of the carrier. In at least one place in the module, the string of PV cells 3 may be electrically connected to the string of energy storage device cells 103a, 103b using a vertical interconnect 105 which interconnects the conductors 15 of the respective collector-connector 11b. The respective PV cells are spaced apart from each other by spaces 107 and the respective energy storage cells are spaced apart from each other by spaces 109. The PV cells 3 and the energy storage device cells 103 are located between the top and bottom encapsulating layers. The top encapsulating layer 13 shown in FIG. 3 is the insulating carrier 13 of collector-connector 11a. However, a separate, transparent top encapsulating layer may be used instead. Likewise, the bottom encapsulating layer 111 may be replaced by an insulating carrier of a collector-connector.

FIG. 4 illustrates a module according to another embodiment which contains PV cells 3a, 3b which are integrated with the energy storage devices 103a, 103b. Each respective PV cell 3 is electrically connected in parallel with a respective energy storage device 103, such as a thin film battery or capacitor. In this configuration, each PV cell preferably electrically contacts a respective energy storage device 103 instead of being separated from the energy storage device by the insulating carrier. As shown in FIG. 4, the module contains two sheets or ribbons of carrier film 13a, 13b. Each PV cell 3 may be located adjacent to a respective device 103 between the carriers 13a and 13b. Each PV cell 3 may be separated from the adjacent device 103 by spaces 107, which may be unfilled (i.e., air gaps) or filled with electrically insulating material.

Each carrier 13a, 13b is selectively printed with conductors 15a, 15b, respectively, such as conductive traces and/or wires, thus forming a flexible circuit or “decal”. The conductors 15a on carrier 13a contact the front (i.e., the front electrode 7) of the PV cells 3 collecting current generated on the cells and the front of the energy storage devices 103, and the conductors 15b on carrier 13b contact the back side electrodes of the PV cells and the devices 103. Each pair of adjacent conductors 15a, 15b contact each other in region 17 between the PV cells. The front side electrode of each PV cell 3 and each energy storage device 103 is electrically connected to the back side electrode of each respective PV cell to complete the circuit.

The connection in region 17 connects the conductors 15a, 15b both electrically and mechanically to achieve serialization of the module (i.e., the connection of the components in series). The connection methods include direct physical contact (i.e., pressing the conductor traces together), solder (such as SnBi or SnPb), conductive adhesive, embossing, mechanical connection means, solvent bonding or ultrasonic bonding. If desired, the sidewalls of the cells 3 and/or devices 103 may be covered with an insulating spacer to prevent the conductors 15 from short circuiting or shunting the opposite polarity electrodes of the same cell 3 or device 103 to each other.

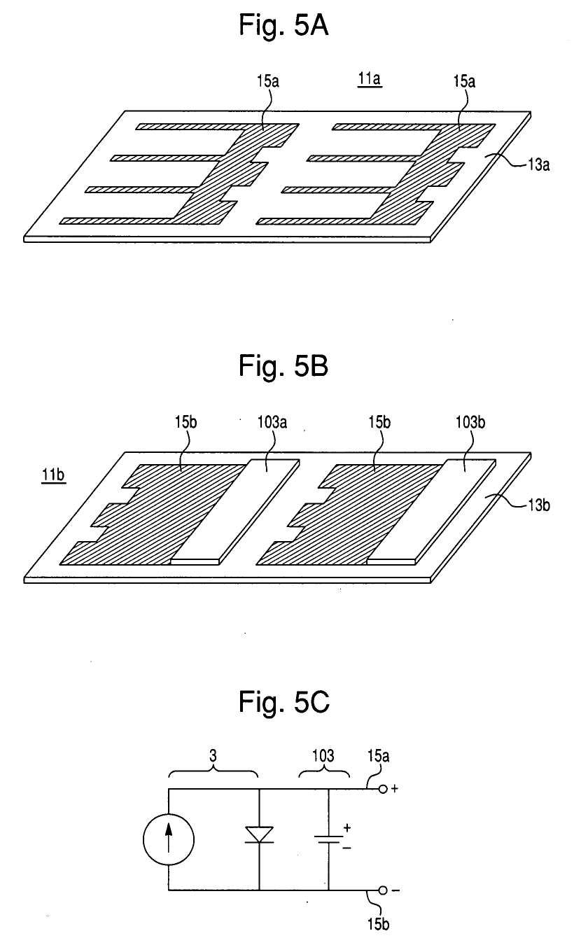

FIG. 5A shows an upside-down three dimensional view of the upper collector-connector 11a of FIG. 4. The conductor 15a comprises traces which contact the front side electrodes 7 of the PV cells 3. FIG. 5B shows a right-side up three dimensional view of the lower collector-connector 11b of FIG. 4. The charge storage devices 103 are formed on the conductors 15b.

If desired, the energy storage device 103 may be used to replace the bypass diode used in prior art PV modules for hot spot protection and to save the power loss in the bypass diode. FIG. 5C illustrates the circuit schematic of a portion of such module. As shown in FIG. 5C, the PV cell 3 and the charge storage device 103 are connected in parallel between the conductors such that the charge storage device 103 takes the place of the bypass diode used in prior art modules.

In summary, the module includes a first flexible sheet or ribbon shaped, electrically insulating carrier 13a supporting a first conductor 15a, and a second flexible sheet or ribbon shaped, electrically insulating carrier 13b supporting a second conductor 15b. The first conductor 15a electrically contacts a major portion of a surface of the first polarity electrode 7 of the first photovoltaic cell 3a. The second conductor 15b electrically contacts the first conductor 15a and at least a portion of the back side electrode of the second photovoltaic cell 3b.

In another embodiment of the invention, the first carrier 13a comprises a passivation material of the module and the second carrier 13b comprises a back support material of the module. In other words, the top carrier film 13a is the upper layer of the module which acts as the passivation and protection film of the module. The bottom carrier film 13b is the back support film which supports the module over the installation location support, such as a roof of a building, vehicle roof (including wings of plane or tops of blimps) or other structure or a solar cell stand or platform (i.e., for free standing photovoltaic modules supported on a dedicated stand or platform). The bottom carrier film may also support auxiliary electronics for connection to junction boxes.

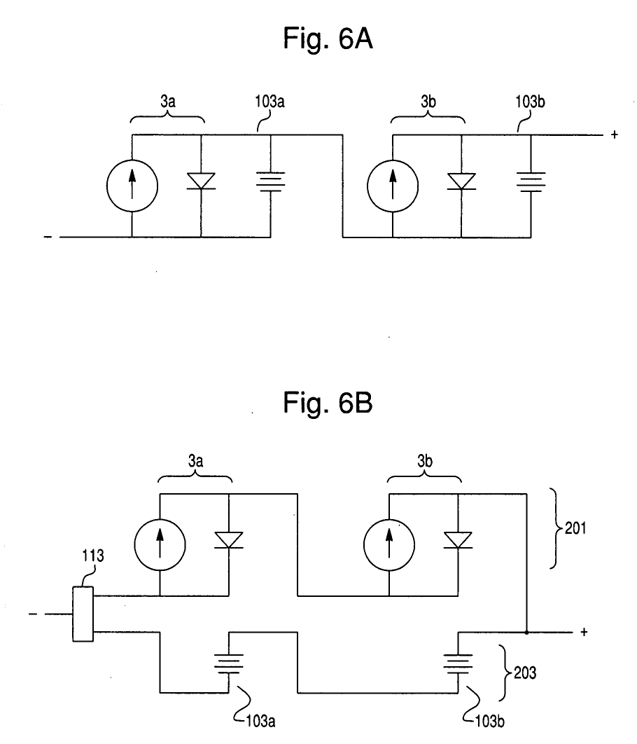

FIG. 6A illustrates an exemplary circuit schematic of a module containing PV cells and energy storage device cells. For example, each PV cell 3a and 3b is connected in parallel with a respective energy storage cell (such as a thin film battery) 103a and 103b. These battery/PV cell pairs (3a/103a and 3b/103b) are then connected in series to form the module. This circuit schematic may be implemented in a module configured similar to the module illustrated in FIG. 4.

FIG. 6B illustrates another exemplary circuit schematic which corresponds to the module illustrated in FIG. 3. In this circuit, the PV cells 3a and 3b are connected in series with each other to form a PV cell string 201. The energy storage device cells 103a and 103b are also connected in series with each other to form an energy storage device string 203. The PV cell string and the energy storage device cell string are then connected in parallel through a charge control device 113. The device 113 controls how much of the current from the PV cells goes into the charge storage devices or into the module output leads. The device 113 may comprise a logic or control chip or circuit which controls the output of the charge storage devices 103. The charge control device 113 may be integrated into the module and uses logic to charge or discharge the energy storage device(s) 103 based on desired output characteristics driven by inverter limits or other external constraints.

While all PV cells 3 are electrically connected to the charge storage devices 103 in the modules described above, it should be noted that only a portion of the PV cells in the module may coupled with energy storage devices 103.

In another embodiment, the modules described above may additionally contain a universal DC port that enables external DC devices, such as charge storage devices, for example batteries, across a range of current or voltage characteristics to be powered or charged. In this embodiment, the external battery or batteries may be plugged into the module through the port to be charged. Once charged, the batteries are disconnected and used for any desired application.

In another embodiment, the module comprises a completely integrated one-piece system that can be used for off-grid or battery back-up applications. This fully integrated module consists the PV cells 3, energy storage devices 103, charge control device 113, as well as an inverter, output connectors and other components needed for the generation, storage, and delivery of usable energy.

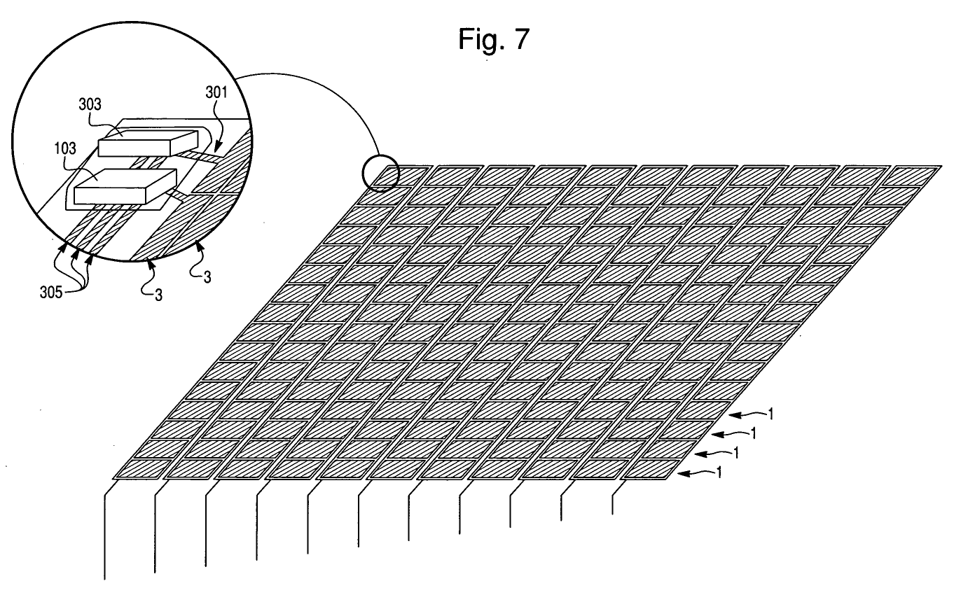

In another embodiment, one or more charge storage devices are integrated into the junction box of the PV module 1. FIG. 7 illustrates an array of 170 PV modules 1. Such an array may be provided on a roof of a building structure, for example. Each module 1 contains a plurality of PV cells 3. Each module also contains a junction box 301, which is shown in FIG. 7 in a three dimensional cut-away view in the close up portion. The junction box 301 contains an inverter 303 and at least one charge storage device 103, such as one or more batteries. If desired, the charge control device 113 may also be integrated into the junction box. The components of the junction box 301 are electrically connected to the main electrical panel or other electrical output of the array by AC bus bars 305.

Although the foregoing refers to particular preferred embodiments, it will be understood that the present invention is not so limited. It will occur to those of ordinary skill in the art that various modifications may be made to the disclosed embodiments and that such modifications are intended to be within the scope of the present invention. All of the publications, patent applications and patents cited herein are incorporated herein by reference in their entirety.

1. A photovoltaic module, comprising:
a first photovoltaic cell;
a second photovoltaic cell; and
an energy storage device integrated into the module.

2. The module of claim 1, wherein the first photovoltaic cell, the second photovoltaic cell and the energy storage device are located between a front encapsulating layer of the module and a back encapsulating layer of the module.

3. The module of claim 2, wherein the charge storage device comprises a thin film rechargeable charge storage device which is electrically connected to at least one of the first and the second photovoltaic cells.

4. The module of claim 3, wherein the energy storage device comprises a battery.

5. The module of claim 3, wherein the energy storage device comprises a capacitor.

6. The module of claim 2, further comprising a collector-connector which comprises an electrically insulating carrier and at least one electrical conductor to form a flexible circuit, wherein the collector-connector is configured to collect current from the first photovoltaic cell and to electrically connect the first photovoltaic cell with the second photovoltaic cell.

7. The module of claim 6, wherein:
the collector-connector electrically contacts a first polarity electrode of the first photovoltaic cell in such a way as to collect current from the first photovoltaic cell; and
the collector-connector directly or indirectly electrically contacts a second polarity electrode of the second photovoltaic cell to electrically connect the first polarity electrode of the first photovoltaic cell to the second polarity electrode of the second photovoltaic cell.

8. The module of claim 7, wherein:
the first and the second photovoltaic cells comprise plate shaped cells which are located adjacent to each other;
the first polarity electrode of the first photovoltaic cell comprises an optically transparent front side electrode which is adapted to face the Sun;
the second polarity electrode of the second photovoltaic cell comprises a back side electrode which is adapted to face away from the Sun;
the carrier comprises a flexible sheet or ribbon;
the at least one electrical conductor comprises a plurality of flexible, electrically conductive wires or traces supported by the carrier;
the wires or the traces electrically contact a major portion of a surface of the first polarity electrode of the first photovoltaic cell; and
the wires or the traces directly or indirectly electrically contact at least a portion of the second polarity electrode of the second photovoltaic cell to electrically connect it to the first polarity electrode of the first photovoltaic cell.

9. The module of claim 8, wherein:
the at least one electrical conductor comprises a conductor located on a first side of the carrier;
at least a first part of carrier is located over a front surface of the first photovoltaic cell such that the conductor electrically contacts the first polarity electrode on the front side of the first photovoltaic cell; and
an electrically conductive tab electrically connects the conductor to the second polarity electrode of the second photovoltaic cell.

10. The module of claim 6, further comprising a second collector-connector located below the first and the second photovoltaic cells and above the charge storage device.

11. The module of claim 10, wherein the second collector-connector is configured to collect current from the energy storage device and to electrically connect the energy storage device with a second energy storage device.

12. The module of claim 6, wherein the first photovoltaic cell and the charge storage device are electrically connected in parallel and are located adjacent to each other between the collector-connector and a second collector-connector.

13. The module of claim 1, wherein the module lacks a bypass diode and the charge storage device is configured to replace the bypass diode for hot spot protection.

14. The module of claim 13, wherein the first photovoltaic cell and the charge storage device are electrically connected in parallel.

15. The module of claim 1, wherein:
the first photovoltaic cell and the charge storage device are electrically connected in parallel to form a first device pair;
the second photovoltaic cell is electrically connected in parallel to a second charge storage device to form a second device pair; and
the first device pair is electrically connected in series to the second device pair.

16. The module of claim 1, wherein:
the first photovoltaic cell and the second photovoltaic cell are electrically connected in series to form a first string;
the charge storage device is electrically connected in series to a second charge storage device to form a second string; and
the first string is electrically connected in parallel to the second string.

17. The module of claim 1, further comprising a charge control device which is integrated into the module and which is configured to control an output of the charge storage device.

18. The module of claim 1, further comprising a universal DC port which is configured to enable external DC devices to be powered or charged by the module.

19. The module of claim 1, wherein the module comprises a completely integrated one-piece system that is configured to be used for off-grid or battery back-up applications.

20. A photovoltaic module comprising:
a plurality of photovoltaic cells; and
a junction box comprising an inverter and at least one charge storage device.
